(19) United States
(12) Patent Application Publication
(10) Pub. No.: US 2025/0160066 A1
(43) Pub. Date: May 15, 2025

(54) MICRO LED, MICRO LED DISPLAY PANEL AND EPITAXIAL STRUCTURE

(71) Applicant: JADE BIRD DISPLAY (SHANGHAI) LIMITED, SHANGHAI (CN)

(72) Inventors: Qunchao XU, Shanghai (CN); Weisin TAN, Shanghai (CN)

(21) Appl. No.: 18/940,924

(22) Filed: Nov. 8, 2024

(30) Foreign Application Priority Data
Nov. 9, 2023 (WO) PCT/CN2023/130742

(51) Int. Cl. H01L 33/38; H01L 25/075; H01L 25/16; H01L 33/06; H01L 33/08; H01L 33/60; H01L 33/62

(52) U.S. Cl. CPC H10H 20/8316; H01L 25/0753; H01L 25/167; H10H 20/812; H10H 20/813; H10H 20/856; H10H 20/857

(57) ABSTRACT

A micro LED includes a bonding layer provided at a bottom of the micro LED; a first P type semiconductor layer formed on the bonding layer and electrically connected to the bonding layer; a first light emitting layer formed on the first P type semiconductor layer; a N type semiconductor layer formed on the first light emitting layer; a second light emitting layer formed on the N type semiconductor layer; and a second P type semiconductor layer formed on the second light emitting layer; wherein the first P type semiconductor layer and the second P type semiconductor layer are electrically connected to a first electrode, and the N type semiconductor layer is electrically connected to a second electrode.

### CROSS-REFERENCE TO RELATED APPLICATIONS

The present disclosure claims the benefits of priority to PCT Application No. PCT/CN2023/130742, filed on Nov. 9, 2023, which is incorporated herein by reference in its entirety.

### TECHNICAL FIELD

The present disclosure generally relates to micro LED manufacturing technology, and more particularly, to a micro LED, a micro LED display panel, and an epitaxial structure.

### BACKGROUND

Inorganic micro pixel light emitting diodes, also referred to as micro light emitting diodes, micro LEDs, or μ-LEDs, become more important since they are used in various applications including self-emissive micro-displays, visible light communications, and optogenetics. The micro LEDs have higher output performance than conventional LEDs because of better strain relaxation, improved light extraction efficiency, and uniform current spreading. Compared with conventional LEDs, the micro LEDs also exhibit several advantages, such as improved thermal effects, faster response rate, larger working temperature range, higher resolution, wider color gamut, higher contrast, lower power consumption, and operability at higher current density.

A micro LED can include a light emitting mesa and electrical connection to electrodes, so that the micro LED can be controlled. Since a pitch and a dimension of the micro LED become smaller and smaller, light emission efficiency may seriously degrade.

### SUMMARY OF THE DISCLOSURE

Embodiments of the present disclosure provide a micro LED. The micro LED includes a bonding layer provided at a bottom of the micro LED; a first P type semiconductor layer formed on the bonding layer and electrically connected to the bonding layer; a first light emitting layer formed on the first P type semiconductor layer; an N type semiconductor layer formed on the first light emitting layer; a second light emitting layer formed on the N type semiconductor layer; and a second P type semiconductor layer formed on the second light emitting layer; wherein the first P type semiconductor layer and the second P type semiconductor layer are electrically connected to a first electrode; and the N type semiconductor layer is electrically connected to a second electrode.

Embodiments of the present disclosure also provide a micro LED display panel. The micro LED display panel includes an integrated circuit (IC) backplane comprising a bottom pad array, the bottom pad array comprising a plurality of bottom pads; and a micro LED array formed on the IC backplane, the micro LED array comprising a plurality of micro LEDs; wherein one micro LED of the plurality of micro LEDs is electrically connected to one bottom pad of the plurality of bottom pad, and each of the plurality of micro LEDs includes: a bonding layer bonded with the IC backplane LED; a first P type semiconductor layer formed on the bonding layer and electrically connected to the bonding layer; a first light emitting layer formed on the first P type semiconductor layer; an N type semiconductor layer formed on the first light emitting layer; a second light emitting layer formed on the N type semiconductor layer; and a second P type semiconductor layer formed on the second light emitting layer; wherein the first P type semiconductor layer and the second P type semiconductor layer are electrically connected to a first electrode; and the N type semiconductor layer is electrically connected to a second electrode.

Embodiments of the present disclosure also provide an epitaxial structure. The epitaxial structure includes a substrate provided at a bottom of the epitaxial structure; an intermediate layer formed on the substrate; a first P type epitaxial layer formed on the intermediate layer; a first light emitting layer formed on the first P type epitaxial layer; a N type epitaxial layer formed on the first light emitting layer; a second light emitting layer formed on the N type epitaxial layer; and a second P type epitaxial layer formed on the second light emitting layer.

### BRIEF DESCRIPTION OF THE DRAWINGS

Embodiments and various aspects of the present disclosure are illustrated in the following detailed description and the accompanying figures. Various features shown in the figures are not drawn to scale.

FIG. 1 illustrates a structural diagram showing a sectional view of an exemplary epitaxial structure, according to some embodiments of the present disclosure.

FIG. 2 illustrates a structural diagram showing an example process of transferring the epitaxial structure shown in FIG. 1 to a silicon wafer, according to some embodiments of the present disclosure.

FIG. 3 illustrates a structural diagram showing a top view of an example micro LED, according to some embodiment of the present disclosure.

FIG. 4 illustrates a structural diagram shown in a sectional view along an A-A′ direction of the micro LED shown in FIG. 3, according to some embodiments of the present disclosure.

FIG. 5 is a circuit diagram schematically illustrating two light emitting layers shown in FIG. 4 electrically connected in parallel, according to some embodiments of the present disclosure.

FIG. 6 illustrates a structural diagram showing a top view of another example micro LED, according to some embodiment of the present disclosure.

FIG. 7 illustrates a structural diagram shown in a sectional view along a B-B′ direction of the micro LED shown in FIG. 6, according to some embodiments of the present disclosure.

FIG. 8 is a circuit diagram schematically illustrating two light emitting layers shown in FIG. 7 electrically connected in parallel, according to some embodiments of the present disclosure.

FIG. 9 illustrates a structural diagram showing a sectional view of an exemplary micro LED display panel, according to some embodiments of the present disclosure.

FIG. 10 illustrates a structural diagram showing a sectional view of another exemplary micro LED display panel, according to some embodiments of the present disclosure.

FIG. 11 illustrates a structural diagram showing a top view of an exemplary micro LED display panel, according to some embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations consistent with the invention. Instead, they are merely examples of apparatuses and methods consistent with aspects related to the invention as recited in the appended claims. Particular aspects of the present disclosure are described in greater detail below. The terms and definitions provided herein control, if in conflict with terms and/or definitions incorporated by reference.

Embodiments of the present disclosure provide a micro LED to improve light emission efficiency. The micro LED includes multiple light emitting layers.

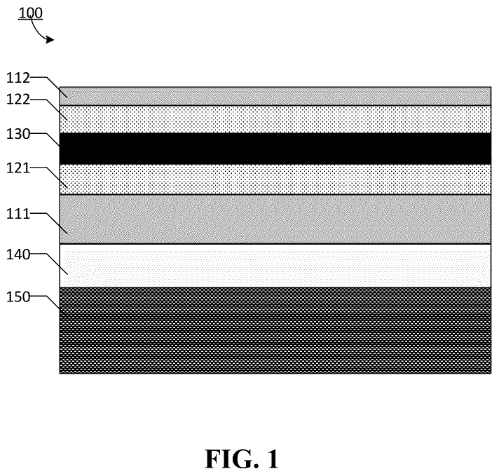

FIG. 1 illustrates a structural diagram showing a sectional view of an exemplary epitaxial structure 100, according to some embodiments of the present disclosure. As shown in FIG. 1, epitaxial structure 100 includes a substrate 150 provided at a bottom of epitaxial structure 100. In some embodiments, a material of substrate 150 is sapphire. Epitaxial structure 100 further includes an intermediate layer 140 formed on substrate 150. Intermediate layer 140 and substrate 150 are to be removed when transferring epitaxial structure to a silicon wafer to form a micro LED. In some embodiments, for a sapphire-based epitaxy (EPI) wafer and an Si-based EPI wafer, intermediate layer 140 includes a buffer layer and an unintentional dopped (UID) layer. The buffer layer is formed on substrate 150, and the UID layer is formed on the buffer layer. In this example, a material of the buffer layer and the UID layer is GaN, and the UID layer is an un-doped layer. For a GaAs-based EPI wafer, intermediate layer 140 includes an etch-stop layer and a buffer layer. The buffer layer is formed on substrate 150, and the etch-stop layer is formed on the buffer layer. In this example, a material of the buffer layer is GaAs, and a material of the etch-stop layer is Al_{0.15}GaInP. Epitaxial structure 100 further includes a plurality of epitaxial layers and two light emitting layers. Referring to FIG. 1, epitaxial structure 100 includes a first P type epitaxial layer 111 formed on intermediate layer 140, a first light emitting layer 121 formed on first P type epitaxial layer 111; an N type epitaxial layer 130 formed on first light emitting layer 121; a second light emitting layer 122 formed on N type epitaxial layer 130; and a second P type epitaxial layer 112 formed on second light emitting layer 122. With such structure, epitaxial structure 100 has multiple light emitting layers. Therefore, a micro LED including epitaxial structure 100 can improve light emission efficiency. In some embodiments, each of first light emitting layer 121 and second light emitting layer 122 includes at least one quantum well layer. In some embodiments, first P type epitaxial layer 111 and second P type epitaxial layer 112 are P-GaN, N type epitaxial layer 130 is N-GaN.

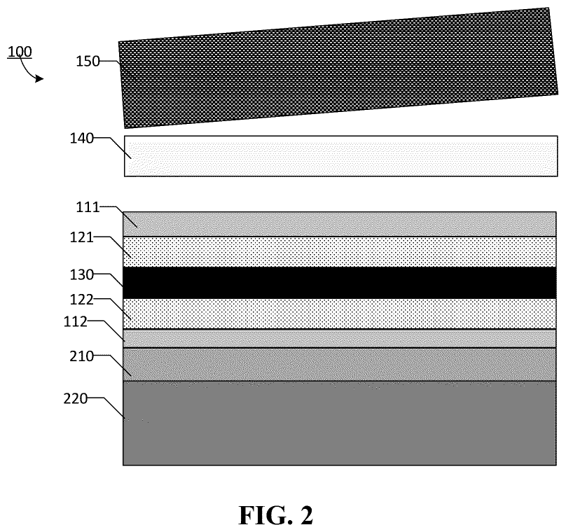

FIG. 2 illustrates a structural diagram showing an example process of transferring epitaxial structure 100 shown in FIG. 1 to a silicon wafer, according to some embodiments of the present disclosure. Referring to FIG. 1 and FIG. 2, epitaxial structure 100 shown in FIG. 1 is inverted and is mounted on a bonding layer 210. Therefore, second P type epitaxial layer 112 is provided on bonding layer 210 and electrically connected to bonding layer 210. Bonding layer 210 is further provided on a silicon wafer 220. In some embodiments, a material of bonding layer 210 is metal. For example, the material may include: Al, Au, Rh, Ag, Cr, Ti, Pt, Sn, Cu, etc. The material may also include one or more metal alloys, for example, AuSn, TiW, and the like. As diagrammatically shown in FIG. 2, during the transferring process, substrate 150 and intermediate layer 140 are removed. For example, for a sapphire-based EPI wafer, sapphire substrate 150 can be removed by LLO (laser lift off), and intermediate layer 140 can be etched by ICP (inductively coupled plasma), RIE (Reactive Ion Etching), or IBE (Ion Beam Etching). For an Si-based EPI wafer, Si substrate 150 can be removed by one or more of grinding, polishing, dry etch (ICP, RIE, or IBE), or wet etch (such as mixed HNO₃ and HF), and intermediate layer 140 can be etched by ICP, RIE, IBE. For a GaAs-based EPI wafer, GaAs substrate 150 can be removed by wet-etch (such as mixed NH₄OH and H₂O₂), and intermediate layer 140 (i.e., an etch-stop layer) can be etched by HCl or mixed HCl and H₃PO₄. After completing the transferring process, the layered structure is ready for manufacturing micro LEDs.

In some embodiments, first light emitting layer 121 and second light emitting layer 122 emit light of the same color. In some embodiments, first light emitting layer 121 and second light emitting layer 122 emit light of different colors.

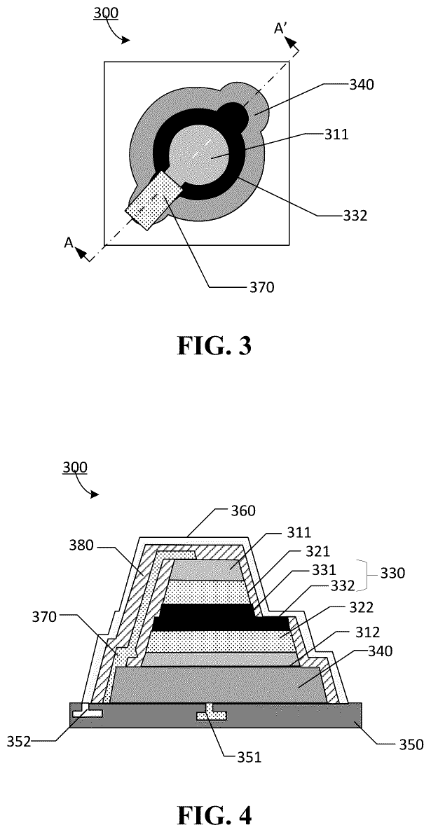

FIG. 3 illustrates a structural diagram showing a top view of an example micro LED 300, according to some embodiment of the present disclosure. FIG. 4 illustrates a structural diagram shown in a sectional view along an A-A′ direction of micro LED 300 shown in FIG. 3, according to some embodiments of the present disclosure. Micro LED 300 is made from the layered structure shown in FIG. 2. Referring to FIG. 3 and FIG. 4, micro LED 300 includes a first P type semiconductor layer 311, a first light emitting layer 321, a N type semiconductor layer 330, a second light emitting layer 322, a second P type semiconductor layer 312, and a bonding layer 340 from top to bottom. Second P type semiconductor layer 312 is electrically connected to bonding layer 340. First P type semiconductor layer 311 and second P type semiconductor layer 312 are electrically connected to a first electrode (e.g., P-pad) further described below. N type semiconductor layer 330 is electrically connected to a second electrode (e.g., N-pad) further described below. Therefore, the two light emitting light layer (e.g., first light emitting layer 321 and second light emitting layers 322) can be regarded as electrically connected in parallel.

Referring to FIG. 4, in this example, micro LED 300 further includes a connection structure 370 electrically connecting first P type semiconductor layer 311 and second P type semiconductor layer 312 to the first electrode. A top of connection structure 370 is electrically connected to first P type semiconductor layer 311, and a bottom of connection structure 370 is electrically connected to bonding layer 340. Since second P type semiconductor layer 312 is electrically connected to bonding layer 340, both first P type semiconductor layer 311 and second P type semiconductor layer 312 are electrically connected to bonding layer 340. Bonding layer 340 is further bonded to an integrated circuit (IC) backplane 350 by a bottom pad 351, as the first electrode (e.g., P-pad). In this example, bottom pad 351 is a P-pad.

In some embodiments, micro LED 300 further includes a top conductive layer 360 covering micro LED 300. Top conductive layer 360 is formed on a surface of micro LED 300. Top conductive layer 360 is electrically connected to N type semiconductor layer 330. Top conductive layer 360 is further electrically connected to the second electrode (e.g., N-pad). For example, in this example, a top pad 352 is provided on IC backplane 350 and serves as the second electrode (e.g., N-pad). In some embodiments, bottom pad 351 and top pad 352 can be connected to an internal circuit of IC backplane 350 and controlled to be on/off. In some embodiments, N type semiconductor layer 330 includes a second N type semiconductor layer 332 formed on second light emitting layer 322, and a first N type semiconductor layer 331 formed on second N type semiconductor layer 332. Second N type semiconductor layer 332 extends outwards from first N type semiconductor layer 331 and the extended top surface of second N type semiconductor layer 332 is electrically connected to top conductive layer 360. During a manufacturing process, N type semiconductor layer 330 can be etched to a stop to form first N type semiconductor layer 331 and second N type semiconductor layer 332. First P type semiconductor layer 311, first light emitting layer 321 and first N type semiconductor layer 331 form a first light emitting mesa. Second N type semiconductor layer 332, second light emitting layer 322 and second P type semiconductor layer 312 form a second light emitting mesa. In some embodiments, connection structure 370 is a metal structure provided at a side of the mesa structures. In some embodiments, top conductive layer 360 is a TCO (transparent conductive oxide) thin layer, for example, an ITO (Indium Tin Oxide) layer, an AZO (Antimony doped Zinc Oxide) layer, an ATO (Antimony doped Tin Oxide) layer, an FTO (Fluorine doped Tin Oxide) layer, and the like.

In some embodiments, micro LED 300 further includes dielectric material 380 filled between top conductive layer 360 and the mesa structures (including the first light emitting mesa and the second light emitting mesa) and around connection structure 370 to isolate unexpected electrically connection among top conductive layer 360, the mesa structures, and connection structure 370. Dielectric material 380 is transparent. A material of dielectric material 380 can be selected from one or more of SiO₂, SiON, Al₂O₃, or SiN, etc.

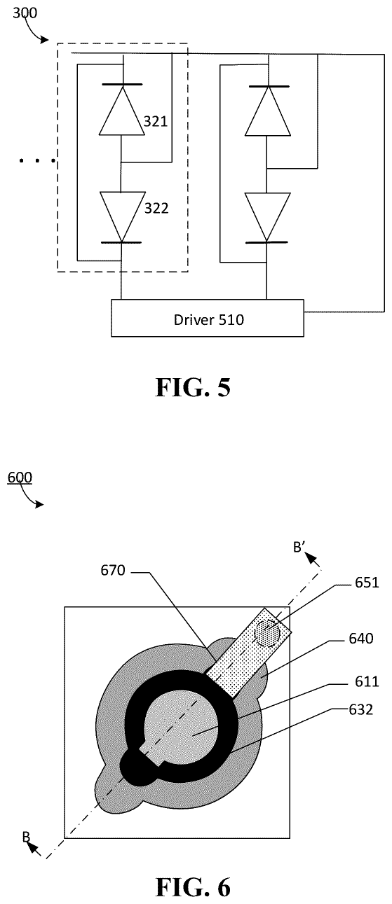

FIG. 5 is a circuit diagram schematically illustrating the two light emitting layers shown in FIG. 4 electrically connected in parallel, according to some embodiments of the present disclosure. A diode can be regarded as a light emitting mesa including a light emitting layer (e.g., first light emitting layer 321 and second light emitting layer 322). As shown in FIG. 5, first light emitting layer 321 or second light emitting layer 322 are electrically connected in parallel. A driver 510 can be connected to micro LED 300 and configured to control each micro LED 300 respectively. In some embodiments, driver 510 can be integrated into IC backplane 350.

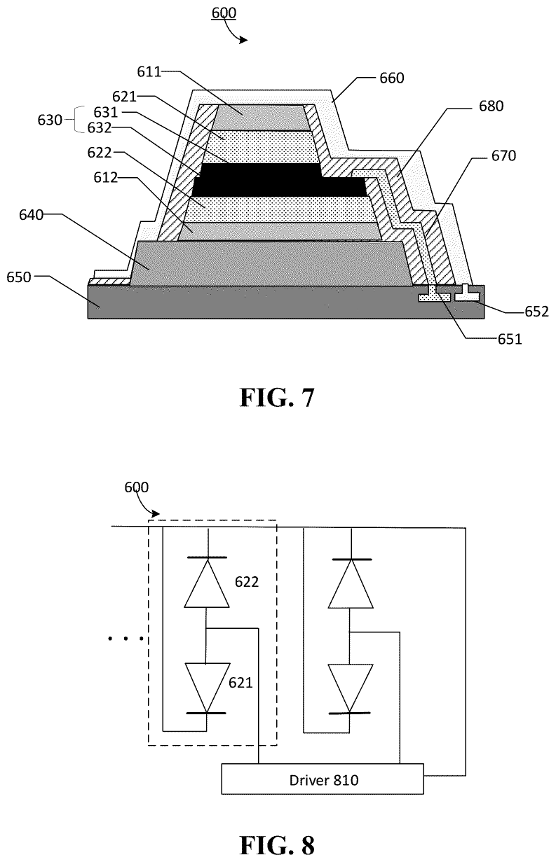

FIG. 6 illustrates a structural diagram showing a top view of another example micro LED 600, according to some embodiment of the present disclosure. FIG. 7 illustrates a structural diagram shown in a sectional view along a B-B′ direction of micro LED 600 shown in FIG. 6, according to some embodiments of the present disclosure. Micro LED 600 is made from the layered structure shown in FIG. 2. Referring to FIG. 6 and FIG. 7, micro LED 600 includes a first P type semiconductor layer 611, a first light emitting layer 621, a N type semiconductor layer 630, a second light emitting layer 622, a second P type semiconductor layer 612, and a bonding layer 640 from top to bottom. Second P type semiconductor layer 612 is electrically connected to bonding layer 640. First P type semiconductor layer 611 and second P type semiconductor layer 612 are electrically connected to a first electrode (e.g., P-pad) further described below. N type semiconductor layer 630 is electrically connected to a second electrode (e.g., N-pad) further described below. Therefore, the two light emitting layers (e.g., first light emitting layer 621 and second light emitting layer 622) can be regarded as electrically connected in parallel.

Referring to FIG. 7, in this example, micro LED 600 further includes a connection structure 670 electrically connecting N type semiconductor layer 630 to a bottom pad 651, i.e., the second electrode (e.g., N-pad), of an IC backplane 650. In this example, bottom pad 651 is an N-pad. A top of connection structure 670 is electrically connected to N type semiconductor layer 630, and a bottom of connection structure 670 is electrically connected to bottom pad 651, i.e., the second electrode. In some embodiments, N type semiconductor layer 630 includes a second N type semiconductor layer 632 formed on second light emitting layer 622, and a first N type semiconductor layer 631 formed on second N type semiconductor layer 632. Second N type semiconductor layer 632 extends outwards from first N type semiconductor layer 631 and the extended top surface of second N type semiconductor layer 632 is electrically connected to connection structure 670. During a manufacturing process, N type semiconductor layer 630 can be etched to a stop to form first N type semiconductor layer 631 and second N type semiconductor layer 632. First P type semiconductor layer 611, first light emitting layer 621, and first N type semiconductor layer 631 form a first light emitting mesa. Second N type semiconductor layer 632, second light emitting layer 622 and second P type semiconductor layer 612 form a second light emitting mesa. In some embodiments, connection structure 670 is a metal structure provided at a side of the mesa structures.

In some embodiments, micro LED 600 further includes a top conductive layer 660 covering micro LED 600. Top conductive layer 660 is formed on a surface of micro LED 600. In this example, top conductive layer 660 electrically connects first P type semiconductor layer 611 and second P type semiconductor layer 612 to the first electrode (e.g., P-pad). For example, in this example, a top pad 652 is provided on IC backplane 650 and serves as the first electrode (e.g., P-pad). In some embodiments, bottom pad 651 and top pad 652 can be connected to an internal circuit of IC backplane 650 and controlled to be on/off. In this example, top conductive layer 660 is formed on a top surface of first P type semiconductor layer 611 and is electrically connected to first P type semiconductor layer 611. A bottom of top conductive layer 660 is electrically connected to bonding layer 640. Since second P type semiconductor layer 612 is electrically connected to bonding layer 640, first P type semiconductor layer 611 and second P type semiconductor layer 612 is electrically connected by bonding layer 640 and top conductive layer 660. In some embodiments, top conductive layer 660 is a TCO (transparent conductive oxide) thin layer, for example, an ITO (Indium Tin Oxide) layer, an AZO (Antimony doped Zinc Oxide) layer, an ATO (Antimony doped Tin Oxide) layer, an FTO (Fluorine doped Tin Oxide) layer, and the like.

In some embodiments, micro LED 600 further includes dielectric material 680 filled between top conductive layer 660 and the mesa structures (including the first light emitting mesa and the second light emitting mesa) and around connection structure 670 to isolate unexpected electrically connection among top conductive layer 660, the mesa structures, and connection structure 670. Dielectric material 680 is transparent. A material of dielectric material 680 can be selected from one or more of SiO₂, SiON, Al₂O₃, or SiN, etc.

FIG. 8 is a circuit diagram schematically illustrating the two light emitting layers shown in FIG. 7 electrically connected in parallel, according to some embodiments of the present disclosure. A diode can be regarded as a light emitting mesa including a light emitting layer (e.g., first light emitting layer 621 and second light emitting layer 622). As shown in FIG. 8, first light emitting layer 621 or second light emitting layer 622 are electrically connected in parallel. A driver 810 can be connected to micro LED 600 and configured to control each micro LED 600 respectively. In some embodiments, driver 810 can be integrated into IC backplane 650.

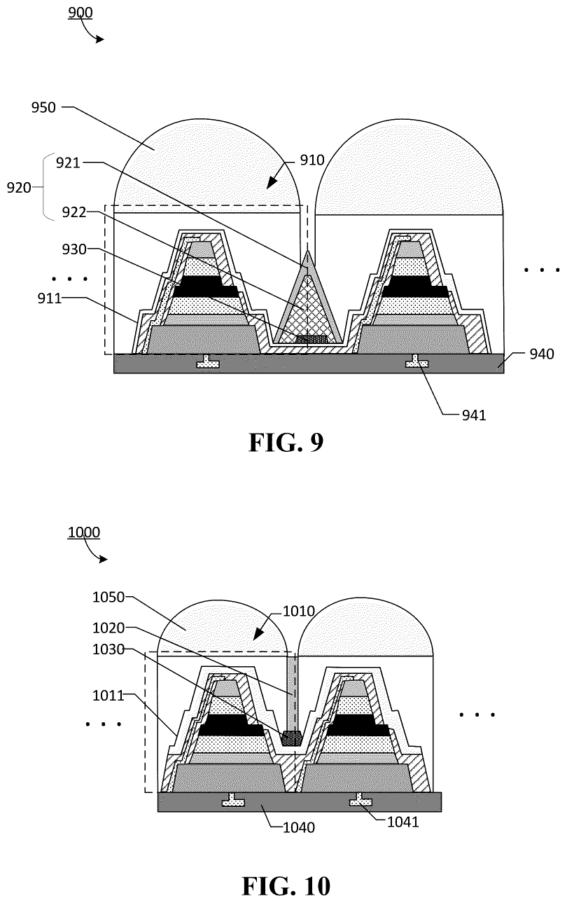

FIG. 9 illustrates a structural diagram showing a sectional view of an exemplary micro LED display panel 900, according to some embodiments of the present disclosure. Micro LED display panel 900 includes a micro LED array including a plurality of micro LEDs 910 and an IC (integrated Circuit) backplane 940. The plurality of micro LEDs 910 are provided on IC backplane 940. In FIG. 9, two adjacent micro LEDs 910 are illustrated for illustrative purpose. It can be understood that more micro LEDs 910 can be included in micro LED display panel 900. Details about micro LED 910 are those described above with reference to micro LED 300 consistent with FIG. 3 to FIG. 5, which will not be repeated herein. It can be understood that micro LED 910 can also be provided as micro LED 600 described above with reference to FIG. 6 to FIG. 8.

As shown in FIG. 9, a top conductive layer 911 of micro LED 910 is interconnected with each of the plurality of micro LEDs 910. That is, top conductive layer 911 is continuously formed on a top of micro LED array and connected with every micro LED 910. Micro LED display panel 900 further includes an enhance pad 930 provided on top conductive layer 911 between the adjacent micro LEDs 910. Enhance pads 930 are interconnected to improve the conductivity of top conductive layer 911. In some embodiments, enhance pad 930 has a mesh structure.

Micro LED display panel 900 further includes an isolation structure 920 provided on top conductive layer 911 and between adjacent micro LEDs 910 to isolate light cross talk between the adjacent micro LEDs 910.

As shown in FIG. 9, in this example, isolation structure 920 has a conical structure. That is, a top surface of isolation structure 920 is smaller than a bottom surface of isolation structure 920. in some embodiments, as shown in FIG. 9, a sectional view of isolation structure 920 is a triangle. In some embodiments, isolation structure 920 includes an isolation core 922 provided on enhance pad 930 and a reflective layer 921 formed on a surface of isolation core 922. Isolation core 922 is provided to form an angle suitable for reflective layer 921. In some embodiments, a material of isolation core 922 is not metal, and a material of the reflective layer 921 is metal. For example, the material of isolation core 922 is an isolation material for absorbing lights. A material of the reflective layer 921 can be any materials with high reflectivity, such as Au, Ag, an omni-directional reflector (ODR), or a distributed Bragg reflector (DBR).

In some embodiments, micro LED 910 includes two light emitting layers, and a top of isolation structure 920 is higher than a top of the upper light emitting layer, and a bottom of isolation structure 920 is provided on top conductive layer 911. Therefore, isolation structure 920 can isolate light cross talk between adjacent micro LEDs 910.

In some embodiments, micro LED display panel 900 further includes a plurality of micro lenses 950 respectively provided above the plurality of micro LED 910, one of the plurality of micro lenses 950 corresponding to one of the plurality of micro LEDs 910.

FIG. 10 illustrates a structural diagram showing a sectional view of another exemplary micro LED display panel 1000, according to some embodiments of the present disclosure. Micro LED display panel 1000 includes a micro LED array including a plurality of micro LEDs 1010 and an IC (integrated Circuit) backplane 1040. The plurality of micro LEDs 1010 are provided on IC backplane 1040. In FIG. 10, two adjacent micro LEDs 1010 are illustrated for illustrative purpose. It can be understood that more micro LEDs 1010 can be included in micro LED display panel 1000. Details about micro LED 1010 are those described above with reference to micro LED 300 consistent with FIG. 3 to FIG. 5, which will not be repeated herein. It can be understood that micro LED 1010 can also be provided as micro LED 600 described above with reference to FIG. 6 to FIG. 8.

As shown in FIG. 10, a top conductive layer 1011 of micro LED 1010 is interconnected with each of the plurality of micro LEDs 1010. That is, top conductive layer 1011 is continuously formed on a top of micro LED array and connected with every micro LED 1010. Micro LED display panel 1000 further includes an enhance pad 1030 provided on top conductive layer 1011 between the adjacent micro LEDs 1010. Enhance pads 1030 are interconnected to improve the conductivity of top conductive layer 1011. In some embodiments, enhance pad 1030 has a mesh structure.

Micro LED display panel 1000 further includes an isolation structure 1020 provided on top conductive layer 1011 and between adjacent micro LEDs 1010 to isolate light cross talk between the adjacent micro LEDs 1010.

As shown in FIG. 10, in this example, isolation structure 1020 has a cylindrical structure. That is a top surface area of isolation structure 1020 is the same as a bottom surface area of isolation structure 1020. In some embodiments, a material of isolation structure 1020 can be any materials with high reflectivity, such as Al, Rh, Au, or Ag.

In some embodiments, micro LED 1010 includes two light emitting layers, and a top of isolation structure 1020 is higher than a top of the upper light emitting layer, and a bottom of isolation structure 1020 is provided on enhance pad 1030. Therefore, isolation structure 1020 can isolate light cross talk between adjacent micro LEDs 1010.

In some embodiments, micro LED display panel 1000 further includes a plurality of micro lenses 1050 respectively provided above the plurality of micro LED 1010, one of the plurality of micro lenses 1050 corresponding to one of the plurality of micro LEDs 1010.

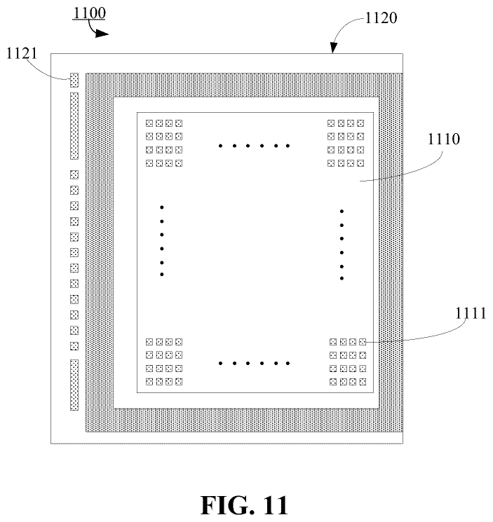

FIG. 11 illustrates a structural diagram showing a top view of a micro LED display panel 1100, according to some embodiments of the present disclosure. Referring to FIG. 11, micro LED display panel 1100 includes a micro LED array 1110 and an IC backplane 1120. Micro LED array 1110 is located on IC backplane 1120 to form an image display area of micro LED display panel 1100. The rest of the area on IC backplane 1120 not covered by micro LED array 1110 is formed as a non-functional area. IC backplane 1120 is formed at the back surface of micro LED array 1110 with a part extending outside of, i.e., not covered by, micro LED array 1110. Micro LED array 1110 includes a plurality of micro LEDs 1111 provided in an array. IC backplane 1120 is configured to control the plurality of micro LEDs 1111. IC backplane 1120 may include a bottom pad array (not shown) corresponding to micro LED array 1110. The bottom pad array includes a plurality of bottom pads (for example, bottom pad 351 in FIG. 4, bottom pad 651 in FIG. 7, bottom pad 941 in FIG. 9, or bottom pad 1041 in FIG. 10) and one bottom pad corresponds to one micro LED 1111. One micro LED of the plurality of micro LEDs is electrically connected with one bottom pad.

In some embodiments, IC backplane 1120 further includes a top connected pad 1121. The top conductive layer (e.g., top conductive layer 360 in FIG. 1, top conductive layer 660 in FIG. 7, top conductive layer 911 in FIG. 9, or top conductive layer 1011 in FIG. 10) is connected with top connected pad 1121, and further may connect to an external circuit (e.g., driver 510 in FIG. 5, or driver 810 in FIG. 8).

Each micro LED herein (e.g., micro LED 300, 600, 910, 1010) has a very small volume. The micro LED can be applied in a micro LED display panel. The light emitting area of the micro LED display panel, e.g., micro LED display panel 1100, is very small, such as 1 mm×1 mm, 3 mm×5 mm, etc. In some embodiments, the light emitting area is the area of the micro LED array in the micro LED display panel. The micro LED display panel includes one or more micro LEDs that form a pixel array in which the micro LEDs are pixels, such as a 1600×1200, 680×480, or 1920×1080-pixel array. The diameter of each micro LED is in the range of about 200 nm to 2 μm. An IC backplane, e.g., IC backplane 1120, is formed at the back surface of micro LED array 1110 and is electrically connected with micro LED array 1110. IC backplane 1120 acquires signals such as image data from outside via signal lines to control corresponding micro LEDs 1111 to emit light or not.

It is understood by those skilled in the art that the micro LED display panel is not limited by the structure described above and may include greater or fewer components than those illustrated, or some components may be combined, or a different component may be utilized.

It should be noted that relational terms herein such as “first” and “second” are used only to differentiate an entity or operation from another entity or operation, and do not require or imply any actual relationship or sequence between these entities or operations. Moreover, the words “comprising,” “having,” “containing,” and “including,” and other similar forms are intended to be equivalent in meaning and be open ended in that an item or items following any one of these words is not meant to be an exhaustive listing of such item or items, or meant to be limited to only the listed item or items.

As used herein, unless specifically stated otherwise, the term “or” encompasses all possible combinations, except where infeasible. For example, if it is stated that a database may include A or B, then, unless specifically stated otherwise or infeasible, the database may include A, or B, or A and B. As a second example, if it is stated that a database may include A, B, or C, then, unless specifically stated otherwise or infeasible, the database may include A, or B, or C, or A and B, or A and C, or B and C, or A and B and C.

In the foregoing specification, embodiments have been described with reference to numerous specific details that can vary from implementation to implementation. Certain adaptations and modifications of the described embodiments can be made. Other embodiments can be apparent to those skilled in the art from consideration of the specification and practice of the invention disclosed herein. It is intended that the specification and examples be considered as exemplary only, with a true scope and spirit of the invention being indicated by the following claims. It is also intended that the sequence of steps shown in figures are only for illustrative purposes and are not intended to be limited to any particular sequence of steps. As such, those skilled in the art can appreciate that these steps can be performed in a different order while implementing the same method.

In the drawings and specification, there have been disclosed exemplary embodiments. However, many variations and modifications can be made to these embodiments. Accordingly, although specific terms are employed, they are used in a generic and descriptive sense only and not for purposes of limitation.

What is claimed is:

1. A micro LED, comprising:
a bonding layer provided at a bottom of the micro LED;
a first P type semiconductor layer formed on the bonding layer and electrically connected to the bonding layer;
a first light emitting layer formed on the first P type semiconductor layer;
a N type semiconductor layer formed on the first light emitting layer;
a second light emitting layer formed on the N type semiconductor layer; and
a second P type semiconductor layer formed on the second light emitting layer; wherein the first P type semiconductor layer and the second P type semiconductor layer are electrically connected to a first electrode, and the N type semiconductor layer is electrically connected to a second electrode.

2. The micro LED according to claim 1, further comprising a connection structure electrically connecting the first P type semiconductor layer and the second P type semiconductor layer to the first electrode.

3. The micro LED according to claim 2, wherein the connection structure is electrically connected to the second P type semiconductor layer and the bonding layer.

4. The micro LED according to claim 2, further comprising a top conductive layer covering the micro LED, wherein the top conductive layer is electrically connected to the N type semiconductor layer.

5. The micro LED according to claim 4, wherein the N type semiconductor layer comprise a first N type semiconductor layer formed on the first light emitting layer, and a second N type semiconductor layer formed on the first N type semiconductor layer; wherein the first N type semiconductor layer extends outwards from the second N type semiconductor layer and a top surface of the first N type semiconductor layer is electrically connected to the top conductive layer.

6. The micro LED according to claim 1, further comprising a connection structure electrically connecting the N type semiconductor layer to the second electrode.

7. The micro LED according to claim 6, further comprising a top conductive layer covering the micro LED, wherein the top conductive layer is electrically connected to the second P type semiconductor layer to the first electrode.

8. The micro LED according to claim 7, wherein the top conductive layer is electrically connected to the bonding layer.

9. The micro LED according to claim 1, wherein the first light emitting layer and the second light emitting layer are configured to emit light of the same color.

10. The micro LED according to claim 1, wherein the first light emitting layer and the second light emitting layer are configured to emit light of different colors.

11. A micro LED display panel comprises:
an integrated circuit (IC) backplane comprising a bottom pad array, the bottom pad array comprising a plurality of bottom pads; and
a micro LED array formed on the IC backplane, the micro LED array comprising a plurality of micro LEDs;
wherein one micro LED of the plurality of micro LEDs is electrically connected to one bottom pad of the plurality of bottom pad, and each of the plurality of micro LEDs comprises:
a bonding layer bonded with the IC backplane LED;
a first P type semiconductor layer formed on the bonding layer and electrically connected to the bonding layer;
a first light emitting layer formed on the first P type semiconductor layer;
a N type semiconductor layer formed on the first light emitting layer;
a second light emitting layer formed on the N type semiconductor layer; and
a second P type semiconductor layer formed on the second light emitting layer;
wherein the first P type semiconductor layer and the second P type semiconductor layer are electrically connected to a first electrode, and the N type semiconductor layer is electrically connected to a second electrode.

12. The micro LED display panel according to claim 11, wherein the micro LED further comprises a top conductive layer covering the micro LED, wherein the top conductive layer of the micro LED is interconnected with each top conductive layer of the plurality of micro LEDs.

13. The micro LED display panel according to claim 12, further comprising an enhance pad provided on the top conductive layer and between adjacent micro LEDs to improve conductivity of the top conductive layer.

14. The micro LED display panel according to claim 13, further comprising an isolation structure provided on the top conductive layer and between adjacent micro LEDs to isolate light cross talk between the adjacent micro LEDs.

15. The micro LED display panel according to claim 14, wherein the isolation structure has a conical structure.

16. The micro LED display panel according to claim 15, wherein the isolation structure comprises an isolation core provided on the enhance pad and a reflective layer formed on a surface of the isolation core.

17. The micro LED display panel according to claim 14, wherein the isolation structure has a cylindrical structure.

18. The micro LED display panel according to claim 11, further comprising a plurality of micro lenses respectively provided above the plurality of micro LEDs, one of the plurality of micro lenses corresponding to one of the plurality of micro LEDs.

19. An epitaxial structure, comprising:
a substrate provided at a bottom of the epitaxial structure;
an intermediate layer formed on the substrate;
a first P type epitaxial layer formed on the intermediate layer;
a first light emitting layer formed on the first P type epitaxial layer;
a N type epitaxial layer formed on the first light emitting layer;
a second light emitting layer formed on the N type epitaxial layer; and
a second P type epitaxial layer formed on the second light emitting layer.

20. The epitaxial structure according to claim 19, wherein a material of the substrate is sapphire.

21. The epitaxial structure according to claim 19, wherein each of the first light emitting layer and the second light emitting layer comprises at least one quantum well layer.
